(19) United States
(12) Patent Application Publication
(10) Pub. No.: US 2012/0255608 A1
(43) Pub. Date: Oct. 11, 2012

(54) BACK-SURFACE-FIELD TYPE OF HETEROJUNCTION SOLAR CELL AND A PRODUCTION METHOD THEREFOR

(75) Inventors: Su Mi Yang, Cheongwon-gun (KR); Sung Bong Roh, Chungju-si (KR); Seok Hyun Song, Yongin-si (KR)

(73) Assignee: HYUNDAI HEAVY INDUSTRIES CO., LTD., Ulsan (KR)

(21) Appl. No.: 13/516,959

(22) PCT Filed: Dec. 17, 2010
(86) PCT No.: PCT/KR2010/009060

§ 371 Date: Jun. 18, 2012

(30) Foreign Application Priority Data
Dec. 21, 2009 (KR) 10-2009-0127928

(51) Int. Cl. H01L 31/075; H01L 31/18

(52) U.S. Cl. 136/256; 438/72; 257/E31.005

(57) ABSTRACT

The back-surface-field type of heterojunction solar cell according to the present invention comprises a crystalline silicon substrate of a first conductivity type, an intrinsic layer and an amorphous silicon layer of the first conductivity type which are laminated in sequence on the front surface of the substrate, an anti-reflective film laminated on the amorphous silicon of the second conductivity type, junction regions of the first conductivity type and junction regions of the second conductivity type which are formed to a predetermined depth on the inside of the substrate from the rear surface of the substrate, and first-conductivity-type electrodes and second-conductivity-type electrodes which are respectively provided on the junction regions of the first conductivity type and the junction regions of the second conductivity type; wherein the first-conductivity-type electrodes and the second-conductivity-type electrodes are disposed alternately.

### TECHNICAL FIELD

The present disclosure relates to a back surface field hetero-junction solar cell and a manufacturing method thereof, and more particularly, to a back surface field hetero-junction solar cell and a manufacturing method thereof, which may maximize photoelectric transformation efficiency of a solar cell by grafting a hetero-junction solar cell and a back surface field solar cell.

### BACKGROUND ART

A solar cell is a core element of solar-light power generation, which directly transforms solar light into electricity, and it may be basically considered as a diode having a p-n junction. Solar light is transformed into electricity by a solar cell as follows. If solar light is incident to a p-n junction of a solar cell, an electron-hole pair is generated, and due to the electric field, electrons move to an n layer and holes move to a p layer, thereby generating photoelectromotive force between the p-n junctions. In this way, if a load or system is connected to both terminals of the solar cell, an electric power may flow to generate power.

A general solar cell is configured to have a front surface and a back electrode respectively at front and back surfaces of the solar cell. Since the front electrode is provided to the front surface which is a light-receiving surface, the light-receiving area decreases as much as the area of the front electrode. In order to solve the decrease of the light-receiving area, a back surface field solar cell has been proposed. The back surface field solar cell maximizes the light-receiving area of the front surface of the solar cell by providing a (+) electrode and a (−) electrode on a back surface of the solar cell.

The solar cell may be regarded as a diode with a p-n junction as described above, which has a junction structure of a p-type semiconductor layer and an n-type semiconductor layer. Generally, the p-type semiconductor layer is formed by implanting p-type impurity ions into a p-type substrate (or, vice versa) to make a p-n junction. As described above, in order to configure a p-n junction of a solar cell, a semiconductor layer into which impurity ions are implanted is inevitable.

However, charges generated by photoelectric transformation may be collected and recombined at interstitial sites or substitutional sites present in a semiconductor layer of the solar cell, while moving, which gives a bad influence on photoelectric transformation efficiency of the solar cell. In order to solve this problem, a so-called hetero-junction solar cell having an intrinsic layer between the p-type semiconductor layer and the n-type semiconductor layer has been proposed, and a rate of recombination of carriers may be lowered by using such a solar cell.

### DISCLOSURE

### Technical Problem

The present disclosure is directed to providing a back surface field hetero-junction solar cell and a manufacturing method thereof, which may maximize photoelectric transformation efficiency of a solar cell by grafting a hetero-junction solar cell and a back surface field solar cell.

### Technical Solution

In one general aspect, the present disclosure provides a back surface field hetero-junction solar cell, which includes: a first conductive crystalline silicon substrate; an intrinsic layer and a first conductive amorphous silicon layer successively formed on a front surface of the substrate; an anti-reflection film formed on the second conductive amorphous silicon; a first conductive junction region and a second conductive junction region formed from a back surface of the substrate to a predetermined depth into the substrate; and a first conductive electrode and a second conductive electrode respectively provided on the first conductive junction region and the second conductive junction region, wherein the first conductive electrode and the second conductive electrode are arranged alternately.

In another general aspect, the present disclosure also provides a manufacturing method of a back surface field hetero-junction solar cell, which includes: preparing a first conductive crystalline silicon substrate; forming a first conductive junction region and a second conductive junction region in a back surface of the substrate to be arranged alternately; successively laminating an intrinsic layer and a first conductive amorphous silicon layer on a front surface of the substrate; forming an anti-reflection film on the first conductive amorphous silicon layer; and forming a first conductive electrode and a second conductive electrode respectively on the first conductive junction region and the second conductive junction region.

The forming of a first conductive junction region or a second conductive junction region may include: forming a screen mask on the back surface of the substrate so that the substrate is selectively exposed at a region where the first conductive junction region or the second conductive junction region is to be formed; applying first conductive or second conductive liquid impurities onto the front surface of the substrate along with the screen mask; and forming a first conductive junction region or a second conductive junction region by thermally treating the substrate.

Before the forming of an anti-reflection film, the manufacturing method may further include forming a buffer layer on the first conductive amorphous silicon layer.

### Advantageous Effects

The back surface field hetero-junction solar cell and manufacturing method thereof according to the present disclosure has the following effects.

Since both a (+) electrode and a (−) electrode are provided on a back surface of a solar cell, the light-receiving area may be maximized. In addition, since an intrinsic layer into which no impurity ion is implanted is provided, a rate of recombination of carriers is minimized, which allows improving photoelectric transformation efficiency of the solar cell.

### DESCRIPTION OF DRAWINGS

The above and other objects, features and advantages of the present disclosure will become apparent from the following description of certain exemplary embodiments given in conjunction with the accompanying drawings, in which:

FIG. 1 is a cross-sectional view of a back surface field hetero-junction solar cell according to an embodiment of the present disclosure; and

FIGS. 2a to 2g are cross-sectional views for illustrating a manufacturing method of the back surface field hetero-junction solar cell according to an embodiment of the present disclosure.

### BEST MODE

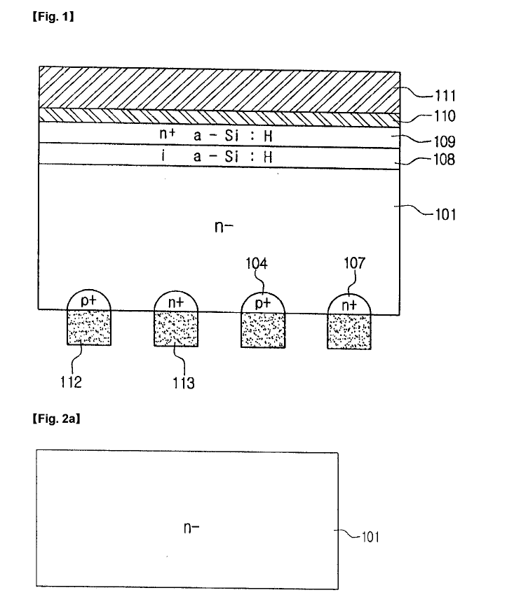

Hereinafter, a back surface field hetero-junction solar cell and a manufacturing method thereof according to an embodiment of the present disclosure will be described with reference to the accompanying drawings. FIG. 1 is a cross-sectional view of a back surface field hetero-junction solar cell according to an embodiment of the present disclosure.

As shown in FIG. 1, a back surface field hetero-junction solar cell according to an embodiment of the present disclosure includes a first conductive crystalline silicon substrate 101. The first conductive type may be p-type or n-type, and the second conductive type is opposite to the first conductive type. The following description will be based on that the first conductive type is n-type and the second conductive type is p-type.

An intrinsic layer 108 and an n-type amorphous semiconductor layer 109 (n+ a-Si:H) are successively formed on the n-type substrate 101 (n−). The intrinsic layer 108 may be configured with an amorphous silicon layer, similar to the n-type amorphous semiconductor layer 109. An anti-reflection film 111 composed of a silicon oxide film or the like is provided on the n-type amorphous semiconductor layer 109. In order to lessen a stress between the n-type amorphous semiconductor layer 109 and the silicon oxide film, a silicon oxide film layer may be further provided as a buffer layer 110.

A p junction region 104 and an n junction region 107 are provided from the back surface of the substrate 101 to a predetermined depth in the substrate 101. The p junction region 104 and the n junction region 107 respectively designate semiconductor regions respectively formed by implanting p-type impurity ions and n-type impurity ions into the n-type substrate 101, and the p junction region 104 and the n junction region 107 are arranged alternately at the back surface of the substrate 101. In addition, a p electrode 112 and an n electrode 113 are respectively provided on the p junction region 104 and the n junction region 107.

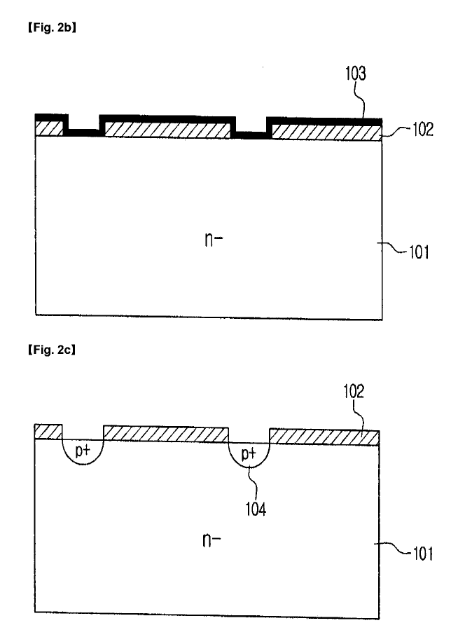

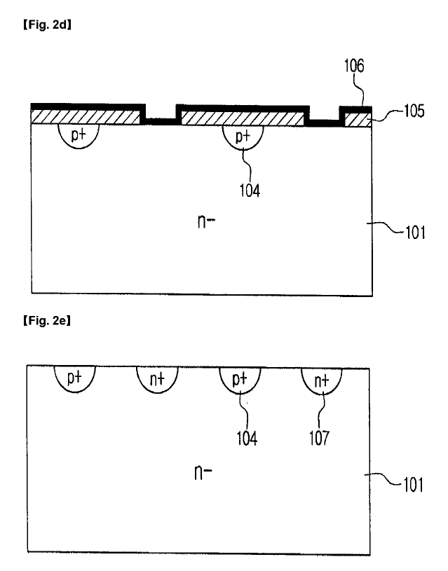

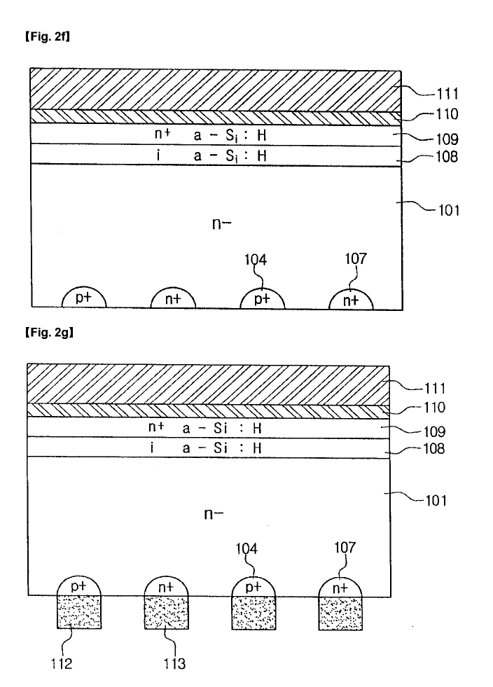

Next, a manufacturing method of the back surface field hetero-junction solar cell according to an embodiment of the present disclosure will be described. FIGS. 2a to 2g are cross-sectional views for illustrating the manufacturing method of the back surface field hetero-junction solar cell according to an embodiment of the present disclosure.

First, as shown in FIG. 2a, a first conductive, for example n-type, crystalline silicon substrate 101 is prepared. After that, a texturing process is performed so that unevenness is formed at the surface of the substrate 101. The texturing process is used for maximizing light absorption and may be performed by using wet etching or dry etching such as reactive ion etching.

Subsequently, a process of forming the p junction region 104 and the n junction region 107 is performed. The process of forming the p junction region 104 and the process of forming the n junction region 107 are independently and successively performed, regardless of their orders.

In a case where the process of forming the p junction region 104 is performed first, as shown in FIG. 2b, a first screen mask 102 is formed on the back surface of the substrate 101 so that a portion of the substrate 101 where the p junction region 104 is to be formed is exposed. After that, p-type liquid impurities 103 are coated to the front surface of the substrate 101 along with the first screen mask 102 by using a roller or the like. Subsequently, a thermal treatment process is performed to diffuse the p-type impurities into the substrate 101, thereby forming the p junction region 104 (see FIG. 2c).

In this state, as shown in FIG. 2d, the first screen mask 102 is removed and a second screen mask 105 is formed on the substrate 101. The second screen mask 105 selectively exposes a portion of the substrate 101 where the n junction region 107 is to be formed. In a state where the second screen mask 105 is formed, n-type liquid impurities 106 are applied to the front surface of the substrate 101. The n-type liquid impurities 106 may be applied by using a roller, similar to the p-type impurities. After that, a thermal treatment process is performed to diffuse the n-type impurities into the substrate 101, thereby forming the n junction region 107 (see FIG. 2e). Subsequently, the second screen mask 105 is removed.

In a state where the p junction region 104 and the n junction region 107 are formed, as shown in FIG. 2f, the intrinsic layer 108 made of amorphous silicon is formed on the substrate 101. The intrinsic layer 108 may be formed by means of plasma enhanced chemical vapor deposition (PECVD) or the like. After that, an n-type amorphous silicon layer (n+ a-Si:H) is formed on the intrinsic layer 108. The n-type amorphous silicon layer may be formed by implanting n-type impurity ions when the amorphous silicon layer is formed.

In this state, the anti-reflection film 111 configured with a silicon nitride film is formed on the n-type amorphous silicon layer. In order to lessen a stress between the anti-reflection film 111 and the n-type amorphous silicon layer, a buffer layer 110 made of a silicon oxide film may be formed on the n-type amorphous silicon layer before the anti-reflection film 111 is formed. Subsequently, if the p electrode 112 and the n electrode 113 are respectively formed on the p junction region 104 and the n junction region 107 as shown in FIG. 2g, the manufacturing method of a back surface field hetero-junction solar cell according to an embodiment of the present disclosure is completed.

### INDUSTRIAL APPLICABILITY

Since both a (+) electrode and a (−) electrode are provided on a back surface of a solar cell, the light-receiving area may be maximized. In addition, since an intrinsic layer into which no impurity ion is implanted is provided, a rate of recombination of carriers is minimized, which allows improving photoelectric transformation efficiency of the solar cell.

While the exemplary embodiments have been shown and described, it will be understood by those skilled in the art that various changes in form and details may be made thereto without departing from the spirit and scope of the present disclosure as defined by the appended claims.

1. A back surface field hetero-junction solar cell, comprising:
a first conductive crystalline silicon substrate;
an intrinsic layer and a first conductive amorphous silicon layer successively formed on a front surface of the substrate;
an anti-reflection film formed on the second conductive amorphous silicon;
a first conductive junction region and a second conductive junction region formed from a back surface of the substrate to a predetermined depth into the substrate; and
a first conductive electrode and a second conductive electrode respectively provided on the first conductive junction region and the second conductive junction region,
wherein the first conductive electrode and the second conductive electrode are arranged alternately.

2. The back surface field hetero-junction solar cell according to claim 1, further comprising a buffer layer between the first conductive amorphous silicon layer and the anti-reflection film.

3. A manufacturing method of a back surface field hetero-junction solar cell, the method comprising:
preparing a first conductive crystalline silicon substrate;
forming a first conductive junction region and a second conductive junction region in a back surface of the substrate to be arranged alternately;
successively laminating an intrinsic layer and a first conductive amorphous silicon layer on a front surface of the substrate;
forming an anti-reflection film on the first conductive amorphous silicon layer; and
forming a first conductive electrode and a second conductive electrode respectively on the first conductive junction region and the second conductive junction region.

4. The manufacturing method of a back surface field hetero-junction solar cell according to claim 3, wherein said forming of a first conductive junction region or a second conductive junction region includes:
forming a screen mask on the back surface of the substrate so that the substrate is selectively exposed at a region where the first conductive junction region or the second conductive junction region is to be formed;
coating first conductive or second conductive liquid impurities onto the front surface of the substrate along with the screen mask; and
forming a first conductive junction region or a second conductive junction region by thermally treating the substrate.

5. The manufacturing method of a back surface field hetero-junction solar cell according to claim 3, before said forming of an anti-reflection film, further comprising:
forming a buffer layer on the first conductive amorphous silicon layer.
